(19) United States
(12) Patent Application Publication
(10) Pub. No.: US 2025/0327221 A1
(43) Pub. Date: Oct. 23, 2025

(54) MESH STRUCTURE AND METHOD FOR MANUFACTURING SAME, ANTENNA REFLECTION MIRROR, ELECTROMAGNETIC SHIELDING MATERIAL, AND WAVEGUIDE TUBE

(71) Applicants: Japan Aerospace Exploration Agency, Tokyo (JP); Technosolver Corporation, Kanagawa (JP); KOYO MATERICA CORPORATION, Aichi (JP); TAIYO WIRE CLOTH CO., LTD., Osaka (JP); NGK INSULATORS, LTD., Aichi (JP)

(72) Inventors: Satoru OZAWA, Chofu-shi (JP); Kentaro NISHI, Chofu-shi (JP); Kazuyuki NAKAMURA, Fujisawa-shi (JP); Masatoshi MORI, Nagoya-shi (JP); Daisuke MATSUMOTO, Osaka-shi (JP); Masaaki AKAIWA, Shenzhen (CN); Ichizo KAWAMURA, Nagoya-shi (JP)

(21) Appl. No.: 19/259,261

(22) Filed: Jul. 3, 2025

Related U.S. Application Data
(63) Continuation of application No. 17/424,201, filed on Jul. 20, 2021.

(30) Foreign Application Priority Data
Jan. 28, 2019 (JP) 2019-012534

(51) Int. Cl. D03D 15/25; C22C 9/00; C25D 7/06; D04B 1/14; D04B 21/12; D06M 11/83; H01P 3/12; H01Q 15/16; H05K 9/00

(52) U.S. Cl. CPC D03D 15/25; C22C 9/00; C25D 7/0607; D04B 1/14; D04B 21/12; D06M 11/83; H01P 3/12; H01Q 15/168; H05K 9/009; D10B 2101/20; D10B 2401/16; D10B 2505/00

(57) ABSTRACT

A mesh structure is a knitted fabric or woven fabric including element wires of a zirconium copper fiber or element wires of a stainless steel fiber.

### CROSS-REFERENCE TO RELATED APPLICATIONS

The present application is a Continuation under 37 C.F.R. § 1.53 (b) of prior U.S. patent application Ser. No. 17/424,201, filed Jul. 20, 2021, in the names of Satoru OZAWA, Kentaro NISHI, Kazuyuki NAKAMURA, Masatoshi MORI, Daisuke MATSUMOTO, Masaaki AKAIWA, and Ichizo KAWAMURA and entitled MESH STRUCTURE AND METHOD FOR MANUFACTURING SAME, ANTENNA REFLECTION MIRROR, ELECTROMAGNETIC SHIELDING MATERIAL, AND WAVEGUIDE TUBE, which is a 35 U.S.C. §§ 371 national phase conversion of PCT/JP2020/002984, filed Jan. 28, 2020, which claims priority of Japanese Patent Application No. 2019-012534, filed Jan. 28, 2019, the contents of which are incorporated by reference herein. The PCT International Application was published in the Japanese language.

### TECHNICAL FIELD

The present invention relates to a mesh structure and a method for manufacturing the same, an antenna reflection mirror including the mesh structure, an electromagnetic shielding material, and a waveguide tube.

### BACKGROUND ART

In the large deployable antennas (LDR) of Engineering Test Satellite type VIII (ETS-VIII) “KIKU No. 8”, a mesh structure made of metal is used for the antenna reflection mirror. This mesh structure is a product obtained by knitting element wires, which are produced by plating molybdenum fibers with gold (element wires of gold-plated molybdenum fibers), with tricot stitch (double atlas stitch). This mesh structure reflects S-band radio waves (see, for example, Non-Patent Document 1).

### CITATION LIST

### Non Patent Document

[Non Patent Document 1]. Kazuhisa Kamegai, Masato Tsuboi, “Measurements of an Antenna Surface for a Millimeter-Wave Space Radio Telescope. II. Metal Mesh Surface for Large Deployable Reflector”, Publ. Astron. Soc. Japan 65, 21, 2013 Feb. 25.

### SUMMARY OF THE INVENTION

### Technical Problem

Since gold-plated molybdenum fibers contain molybdenum, which is a rare metal, there is a concern that it may be difficult to secure resources. Therefore, a mesh structure that uses a material having performance equivalent to that of gold-plated molybdenum fibers in terms of electrical conductivity, elastic modulus, mechanical strength, and the coefficient of thermal expansion, has been desired.

The present invention was made in view of the above-described circumstances, and an object of the present invention is to provide a mesh structure containing a material for which resources can be easily secured and which has performance equivalent to that of a gold-plated molybdenum fiber, a method for manufacturing the mesh structure, and an antenna reflection mirror, an electromagnetic shielding material, and a waveguide tube, all of which include the mesh structure.

### Solution to Problem

In order to solve the above-described problems, the present invention proposes the following means.

The present invention is a mesh structure, which is a knitted fabric or woven fabric including element wires of a zirconium copper fiber or element wires of a stainless steel fiber.

According to the mesh structure related to this invention, since a zirconium copper fiber and a stainless steel fiber have performance equivalent to that of a gold-plated molybdenum fiber in terms of electrical conductivity, elastic modulus, mechanical strength, and the coefficient of thermal expansion, an antenna reflection mirror surface or the like having desired performance is obtained without using molybdenum, which is a rare metal. Furthermore, according to the mesh structure related to this invention, since it is a knitted fabric or woven fabric including a zirconium copper fiber and a stainless steel fiber, the mesh structure can be manufactured at a lower cost than a mesh structure formed of a gold-plated molybdenum fiber.

In addition, the present invention is a method for manufacturing a mesh structure, the method including a step of forming a first knitted fabric or a first woven fabric, both of which include element wires of a zirconium copper fiber or element wires of a stainless steel fiber and element wires of a water-soluble fiber; and a step of immersing the first knitted fabric or the first woven fabric in water to dissolve the element wires of a water-soluble fiber and forming a second knitted fabric or a second woven fabric, both of which include the element wires of the zirconium copper fiber or the element wires of the stainless steel fiber.

According to the method for manufacturing a mesh structure according to this invention, when a first knitted fabric or a first woven fabric is formed, the friction generated between the element wires can be reduced by the element wires of the water-soluble fiber, and breaking of the element wires caused by contact between the element wires can be prevented. Furthermore, the element wires of the water-soluble fiber can be easily removed while maintaining the shape of the first knitted fabric or the first woven fabric.

### Advantageous Effects of Invention

According to the mesh structure related to this invention, resources can be easily secured, and performance equivalent to that of gold-plated molybdenum fibers in terms of electrical conductivity, elastic modulus, mechanical strength, and the coefficient of thermal expansion can be exhibited.

### BRIEF DESCRIPTION OF THE DRAWING(S)

FIG. 1 is a plan view showing a schematic configuration of a mesh structure according to an embodiment of the present invention.

FIG. 2 is a perspective view showing a schematic configuration of an antenna reflection mirror according to an embodiment of the present invention.

FIG. 3 is a perspective view showing a schematic configuration of an electromagnetic shielding material according to an embodiment of the present invention.

FIG. 4 is a perspective view showing a schematic configuration of a waveguide tube according to an embodiment of the present invention.

FIG. 5 shows a schematic configuration of a waveguide tube according to an embodiment of the present invention and is a cross-sectional view taken along the line A-A of FIG. 4.

FIG. 6 is a perspective view showing a schematic configuration of a waveguide tube according to an embodiment of the present invention.

FIG. 7 shows a schematic configuration of a waveguide tube according to an embodiment of the present invention and is a cross-sectional view taken along the line B-B of FIG. 6.

### DESCRIPTION OF EMBODIMENTS

### [Mesh Structure]

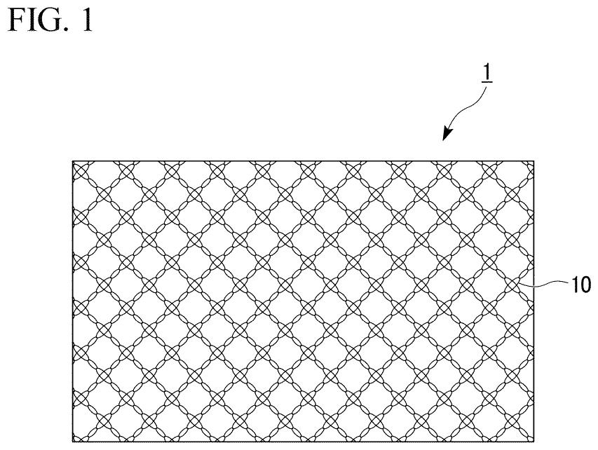

Hereinafter, the mesh structure of the present embodiment will be described with reference to FIG. 1.

FIG. 1 is a plan view showing a schematic configuration of the mesh structure of the present embodiment.

As shown in FIG. 1, the mesh structure 1 of the present embodiment is a knitted fabric including the element wires 10. In other words, the mesh structure 1 of the present embodiment is a knitted fabric formed into a mesh shape (reticulate shape) using the element wires 10.

FIG. 1 shows a case where the mesh structure 1 is a knitted fabric obtained by tricot-knitting the element wires 10. The mesh structure 1 of the present embodiment is not limited to a knitted fabric obtained by tricot-knitting the element wires 10. The mesh structure 1 of the present embodiment may also be a knitted fabric obtained by knitting the element wires 10 with knit stitch, a knitted fabric obtained by knitting the element wires 10 with stockinette stitch, a knitted fabric obtained by knitting the element wires 10 with double atlas stitch, a knitted fabric obtained by knitting the element wires 10 with single satin stitch, or the like.

In a case where the mesh structure 1 is a knitted fabric, the size of the knitting width is not particularly limited and is appropriately adjusted according to the use application of the mesh structure 1 or the like. For example, in a case where the mesh structure 1 is used as an antenna reflection mirror surface, the size of the knitting width of the knitted fabric is adjusted according to the wavelength of the radio waves transmitted and received by the antenna reflection mirror surface.

Furthermore, the mesh structure 1 of the present embodiment may be a woven fabric including the element wires 10. In other words, the mesh structure 1 of the present embodiment may be a plain weave woven fabric obtained by using the element wires 10 as warps and wefts and alternately crossing the warps and the wefts to densely weave up, may be a satin weave woven fabric woven up by lengthily suspending either warps or wefts on the surface of the woven fabric, or may be a twill weave woven fabric obtained by continuously combining three or more strands of warps and wefts up and down to cause diagonal lines to float to the surface of the woven fabric.

The element wire 10 is an element wire of a zirconium copper fiber or an element wire of a stainless steel fiber. The element wire 10 may be a filament of a zirconium copper fiber or a filament of a stainless steel fiber, or may be a bundle of fibers obtained by bundling two or more strands of a filament of a zirconium copper fiber or a filament of a stainless steel fiber.

A zirconium copper fiber is a fiber obtained by wire-drawing an alloy obtained by adding 0.25 at % (atomic percent) to 5.0 at % of zirconium to copper. Zirconium copper fibers have high electrical conductivity, a high elastic modulus, high mechanical strength, and a low coefficient of thermal expansion, and a zirconium copper fiber having an electrical conductivity of 15% IACS to 95% IACS, a mechanical strength of 450 MPa to 2000 MPa, and a coefficient of thermal expansion of about 1.8×10−5/° C. is preferably used.

A stainless steel fiber is a fiber obtained by wire-drawing stainless steel. Stainless steel fibers have high mechanical strength, and a known stainless steel fiber can be used.

The diameter of the element wire 10 is not particularly limited and is appropriately adjusted according to the use application of the mesh structure 1 or the like.

A plating layer may be provided on the surface of the element wire of the zirconium copper fiber or the surface of the element wire of the stainless steel fiber. A plating layer smoothens the surface of the element wire of the zirconium copper fiber and the surface of the element wire of the stainless steel fiber. As a result, in a case where the element wires 10 are knitted into a knitted fabric, the friction generated between the element wires 10 can be reduced, and breaking of the element wires 10 caused by contact between the element wires 10 can be prevented.

Examples of the plating layer include a gold plating layer and a nickel plating layer.

The thickness of the plating layer is not particularly limited as long as the plating layer can smoothen the surface of the element wire of the zirconium copper fiber or the surface of the element wire of the stainless steel fiber wire.

As a method for forming the plating layer, an electrolytic plating method or an electroless plating method is used.

Since the mesh structure 1 of the present embodiment is a knitted fabric or a woven fabric including a zirconium copper fiber or a stainless steel fiber, the mesh structure has pliability capable of forming any shape.

According to the mesh structure 1 of the present embodiment, since the zirconium copper fiber or the stainless steel fiber has performance equivalent to that of a gold-plated molybdenum fiber in terms of electrical conductivity, elastic modulus, mechanical strength, and the coefficient of thermal expansion, an antenna reflection mirror surface or the like having desired performance is obtained without using molybdenum, which is a rare metal. Furthermore, since the mesh structure 1 of the present embodiment is a knitted fabric or woven fabric including a zirconium copper fiber or a stainless steel fiber, the mesh structure 1 can be manufactured at a lower cost than a mesh structure formed of a gold-plated molybdenum fiber.

### [Method for Manufacturing Mesh Structure]

A method for manufacturing a mesh structure of the present embodiment includes a step of forming a first knitted fabric or a first woven fabric, both of which include element wires of a zirconium copper fiber or element wires of a stainless steel fiber and element wires of a water-soluble fiber (hereinafter, referred to as “first step”); and a step of immersing the first knitted fabric or the first woven fabric in water to dissolve the element wires of the water-soluble fiber and forming a second knitted fabric or a second woven fabric, both of which include the element wires of the zirconium copper fiber or element wires of the stainless steel fiber (hereinafter, referred to as “second step”).

Here, the element wire of the zirconium copper fiber or the element wire of the stainless steel fiber may be referred to as “first element wire”, and the element wire of the water-soluble fiber may be referred to as “second element wire”.

In the first step, the first element wires and the second element wires are combined to form a mesh shape, and a first knitted fabric or a first woven fabric is formed. Specifically, the first element wires and the second element wires are bundled to form a bundle of element wires, the bundle of element wires is formed into a mesh shape, and a first knitted fabric or a first woven fabric is formed.

The first element wire may be a filament of a zirconium copper fiber or a filament of a stainless steel fiber, or may be a bundle of fibers obtained by bundling two or more strands of a filament of a zirconium copper fiber or a filament of a stainless steel fiber.

A bundle of the first element wires and the second element wires may be formed by twisting the first element wires and the second element wires, or may be formed such that the first element wires and the second element wires come into contact with each other along the longitudinal direction of each element wire.

In the case of forming a first knitted fabric in the first step, a first knitted fabric is formed by knitting, using a bundle of the first element wires and the second element wires, with tricot stitch, knit stitch, stockinette stitch, double atlas stitch, single satin stitch, or the like.

Furthermore, in a case where the mesh structure is used as, for example, an antenna reflection mirror, the size of the knitting width of the first knitted fabric is adjusted according to the wavelength of the radio waves transmitted and received by the antenna reflection mirror.

In a case where a first woven fabric is formed in the first step, the first woven fabric is formed by weaving, using a bundle of the first element wires and the second element wires, with plain weave, satin weave, twill weave, or the like.

Examples of the resin constituting the element wire of the water-soluble fiber include a resol-type phenol resin, a methylolated urea (urea) resin, a methylolated melamine resin, polyvinyl alcohol, polyethylene oxide, polyacrylamide, and carboxymethyl cellulose; however, the resin is not limited to these, and any known water-soluble resin can be used.

The diameter of the element wire of the water-soluble fiber is not particularly limited and is appropriately adjusted according to the use application of the mesh structure, or the like.

In the second step, the first knitted fabric or the first woven fabric is immersed in water to dissolve the element wires of the water-soluble fiber that forms the first knitted fabric or the first woven fabric, and a second knitted fabric or second woven fabric including the element wires of the zirconium copper fiber or the element wires of the stainless steel fiber is formed. When the first knitted fabric or the first woven fabric is immersed in water, only the element wires of the water-soluble fibers forming the first knitted fabric or the first woven fabric dissolve and disappear, and the element wires of the zirconium copper fiber or the element wires of the stainless steel fiber remain while retaining the shape of the first knitted fabric or the first woven fabric. As a result, a second knitted fabric or second woven fabric including the element wires of the zirconium copper fiber or the element wires of the stainless steel fiber is obtained.

The second knitted fabric is obtained by removing the element wires of the water-soluble fiber from the first knitted fabric. The second woven fabric is obtained by removing the element wires of the water-soluble fiber from the first woven fabric. That is, the second knitted fabric or the second woven fabric is the above-described mesh structure.

When the element wires of the water-soluble fiber are dissolved, the temperature of water is not particularly limited; however, it is preferable that the temperature of water is a temperature at which the element wires of the water-soluble fiber can be dissolved in a short period of time.

According to the method for manufacturing a mesh structure of the present embodiment, since the method has the first step of forming a first knitted fabric or first woven fabric including element wires of a zirconium copper fiber or element wires of a stainless steel fiber and element wires of a water-soluble fiber, when the first knitted fabric or the first woven fabric is formed, the friction generated between the element wires is reduced by the element wires of the water-soluble fiber, and breaking of the element wires caused by contact between the element wires can be prevented. Furthermore, according to the method for manufacturing a mesh structure of the present embodiment, since the method has the second step of immersing the first knitted fabric or the first woven fabric in water to dissolve the element wires of the water-soluble fiber and forming a second knitted fabric or second woven fabric including the element wires of the zirconium copper fiber or the element wires of the stainless steel fiber, a mesh structure that is a knitted fabric or woven fabric including the element wires of the zirconium copper fiber or the element wires of the stainless steel fiber can be obtained by easily removing the element wires of the water-soluble fiber while maintaining the shape of the first knitted fabric or the first woven fabric.

### [Antenna Reflection Mirror]

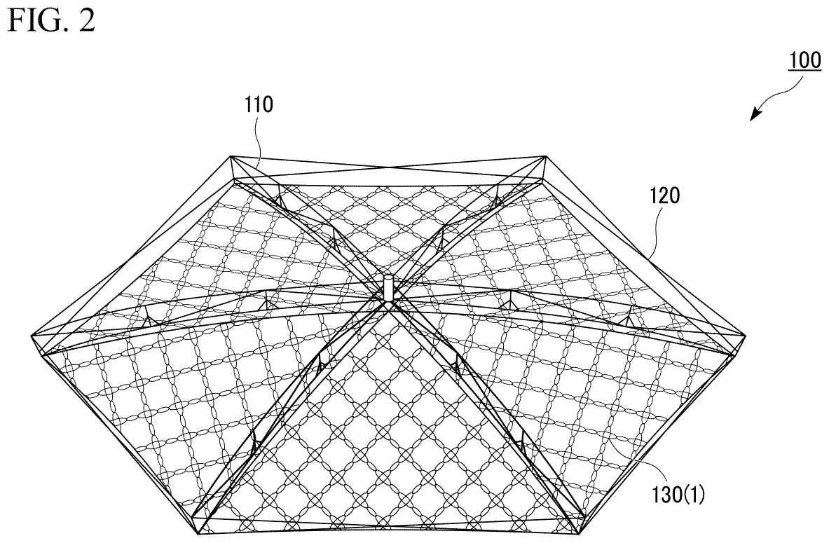

FIG. 2 is a perspective view showing a schematic configuration of an antenna reflection mirror of the present embodiment.

As shown in FIG. 2, the antenna reflection mirror 100 of the present embodiment includes the above-mentioned mesh structure 1. Specifically, in the antenna reflection mirror 100 of the present embodiment, the above-described mesh structure 1 constitutes an antenna reflection mirror surface 130.

As shown in FIG. 2, the antenna reflection mirror 100 of the present embodiment includes an antenna deployment mechanism 110, a band 120 for adjusting the phase angle of the antenna deployment mechanism 110, and an antenna reflection mirror surface 130. In FIG. 2, only the mesh structure 1 constituting the antenna reflection mirror surface 130 is shown as the antenna reflection mirror surface 130.

The antenna deployment mechanism 110 is configured to be deformable between an accommodated state and a deployed state by means of a link mechanism. The antenna deployment mechanism 110 includes, for example, a support member for attaching the mesh structure 1 at positions that become the apexes of a hexagon.

The mesh structure 1 may have foldable pliability.

The antenna reflection mirror 100 is accommodated in the fairing of a rocket in a folded state and is deployed into the deployed shape shown in FIG. 2 in outer space. In the deployed state, an appropriate tension is applied to the mesh structure 1 from the antenna deployment mechanism 110, and the mesh structure 1 spreads out into a predetermined shape and forms the antenna reflection mirror surface 130.

According to the antenna reflection mirror 100 of the present embodiment, since the above-described mesh structure 1 constitutes the antenna reflection mirror surface 130, the zirconium copper fiber or stainless steel fiber constituting the mesh structure 1 has performance equivalent to that of gold-plated molybdenum fibers in terms of electrical conductivity, elastic modulus, mechanical strength, and the coefficient of thermal expansion, and therefore, an antenna reflection mirror having desired communication performance (reflection performance) is obtained.

### [Electromagnetic Shielding Material]

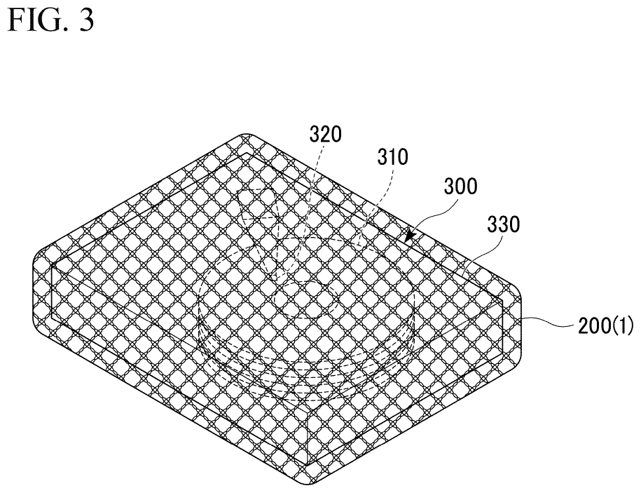

FIG. 3 is a perspective view showing the schematic configuration of an electromagnetic shielding material of the present embodiment.

As shown in FIG. 3, the electromagnetic shielding material 200 of the present embodiment includes the above-mentioned mesh structure 1.

As shown in FIG. 3, the electromagnetic shielding material 200 of the present embodiment is used, for example, so as to cover the outer periphery of a magnetic storage device 300.

The magnetic storage device 300 includes a magnetic disk 310; a head 320 that performs writing into and reading from the magnetic disk 310; and a housing 330 that accommodates the magnetic disk 310 and the head 320.

In a case where the mesh structure 1 constitutes the electromagnetic shielding material 200, the size of the knitting width of the mesh structure 1 is adjusted according to the intended shielding property.

Here, a case where the electromagnetic shielding material 200 covers the outer periphery of the housing 330 has been illustrated; however, the present embodiment is not limited to this case. The electromagnetic shielding material 200 of the present embodiment may be integrated with the housing 330. That is, the electromagnetic shielding material 200 may be embedded in the housing 330, or the electromagnetic shielding material 200 may be adhered to the outer peripheral surface of the housing 330.

The electromagnetic shielding material 200 of the present embodiment can be used in order to electromagnetically shield, for example, electronic equipment, devices, and the like, such as a personal computer, a mobile telephone, and a display, without limiting the target equipment.

According to the electromagnetic shielding material 200 of the present embodiment, since the electromagnetic shielding material includes the above-mentioned mesh structure 1, the zirconium copper fiber or stainless steel fiber constituting the mesh structure 1 has performance equivalent to that of gold-plated molybdenum fibers in terms of electrical conductivity, elastic modulus, mechanical strength, and the coefficient of thermal expansion, and an electromagnetic shielding material having a desired shielding property is obtained.

### [Waveguide Tube]

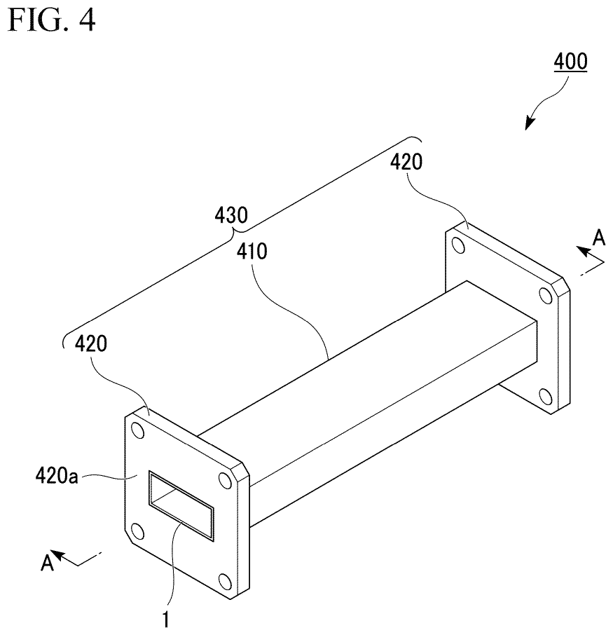

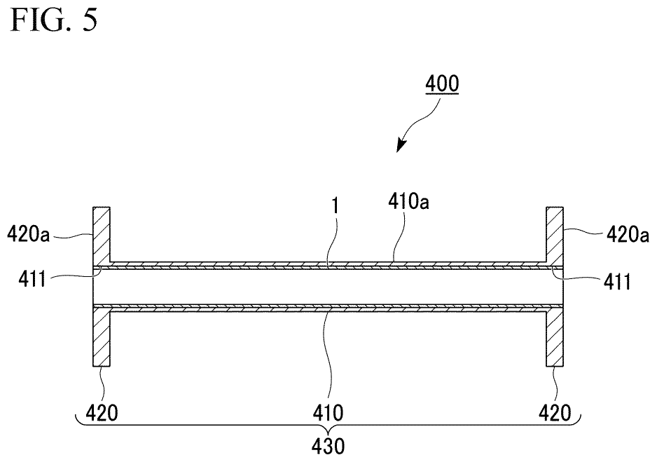

FIG. 4 is a perspective view showing the schematic configuration of a waveguide tube of the present embodiment. FIG. 5 shows the schematic configuration of the waveguide tube of the present embodiment and is a cross-sectional view taken along the line A-A of FIG. 4.

The waveguide tube 400 of the present embodiment includes the above-mentioned mesh structure 1, as shown in FIG. 4 and FIG. 5.

The waveguide tube 400 of the present embodiment includes a waveguide tube main body 430 including a waveguide part 410 formed from a tube (hollow body) whose cross-sectional shape that is perpendicular to the longitudinal direction is a rectangular shape, and flanges 420 and 420 both connected to the two ends of the waveguide part 410; and a mesh structure 1 disposed along an inner surface 410a inside the waveguide part 410.

Openings 411 of the waveguide part 410 are provided at the flanges 420, and the waveguide part 410 is opened at a surface 420a of the flanges 420.

The waveguide tube main body 430 is composed of a carbon fiber-reinforced plastic containing a resin such as an epoxy resin as a matrix material, and carbon fibers as a reinforcing material.

According to the waveguide tube 400 of the present embodiment, since the above-mentioned mesh structure 1 is disposed along the inner surface 410a of the waveguide part 410 of the waveguide tube main body 430 made of CFRP, electromagnetic waves can be transmitted inside the waveguide part 410 without forming an electroconductive coating film by gold plating or the like on the inner surface 410a of the waveguide part 410. That is, according to the waveguide tube 400 of the present embodiment, the manufacturing cost can be reduced because a step of forming an electroconductive coating film on the inner surface 410a of the waveguide part 410 by gold plating or the like as in conventional cases becomes unnecessary.

With regard to the waveguide tube 400 of the present embodiment, a case where the cross-sectional shape perpendicular to the longitudinal direction of the waveguide part 410 is a rectangular shape has been illustrated; however, the present embodiment is not limited to this. With regard to the waveguide tube 400 of the present embodiment, the cross-sectional shape perpendicular to the longitudinal direction of the waveguide part 410 may be a square shape, a circular shape, an elliptical shape, or the like.

### [Waveguide Tube]

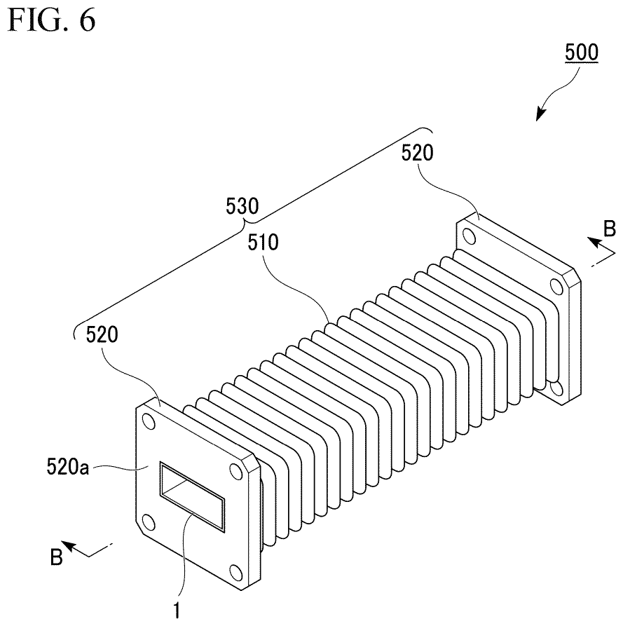

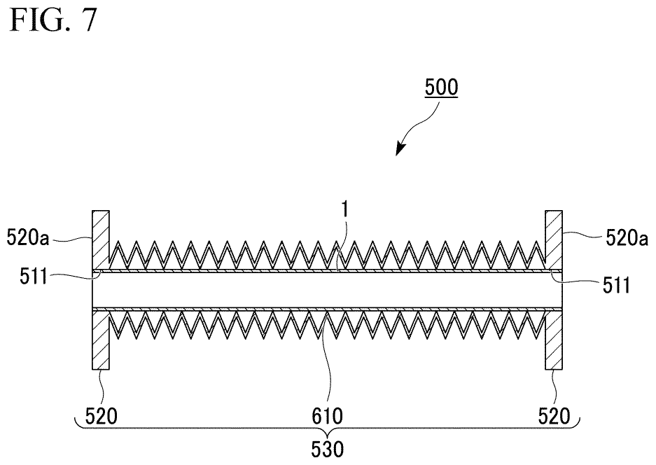

FIG. 6 is a perspective view showing a schematic configuration of the waveguide tube of the present embodiment. FIG. 7 shows a schematic configuration of the waveguide tube of the present embodiment and is a cross-sectional view taken along the line B-B of FIG. 6.

A waveguide tube 500 of the present embodiment includes the above-mentioned mesh structure 1, as shown in FIG. 6 and FIG. 7.

The waveguide tube 500 of the present embodiment includes a waveguide tube main body 530 including a bellows hose-shaped waveguide part 510 formed from a tube (hollow body) whose cross-sectional shape that is perpendicular to the longitudinal direction is a rectangular shape, and flanges 520 and 520 both connected to the two ends of the waveguide part 510; and a mesh structure 1 lining the waveguide part 510.

Openings 511 of the waveguide part 510 are provided at the flanges 520, and the waveguide part 510 is opened at a surface 520a of the flanges 520.

The waveguide tube main body 530 is formed of a metal, a plastic, a carbon fiber-reinforced plastic, or the like.

Since the waveguide tube 500 of the present embodiment has a bellows hose-shaped waveguide part 510 and the above-mentioned mesh structure 1 lining the waveguide part 510, the waveguide tube 500 has pliability (flexibility).

According to the waveguide tube 500 of the present embodiment, since the above-mentioned mesh structure 1 is lining the bellows hose-shaped waveguide part 510, a smooth waveguide formed from the mesh structure 1 can be formed inside the waveguide part 510. As a result, the loss of electromagnetic waves transmitted in the waveguide part 510 can be reduced.

With regard to the waveguide tube 500 of the present embodiment, a case where the cross-sectional shape perpendicular to the longitudinal direction of the waveguide part 510 is a rectangular shape has been illustrated; however, the present embodiment is not limited to this. With regard to the waveguide tube 500 of the present embodiment, the cross-sectional shape perpendicular to the longitudinal direction of the waveguide part 510 may be a square shape, a circular shape, an elliptical shape, or the like.

### INDUSTRIAL APPLICABILITY

The above-described mesh structure can have the resources easily secured and can exhibit performance equivalent to that of gold-plated molybdenum fibers in terms of electrical conductivity, elastic modulus, mechanical strength, and the coefficient of thermal expansion.

### REFERENCE SIGNS LIST

1: Mesh structure
10: Element wire
100: Antenna reflection mirror
110: Antenna deployment mechanism
120: Band
130: Antenna reflection mirror surface
200: Electromagnetic shielding material
300: Magnetic storage device
310: Magnetic disk
320: Head
330: Housing
400, 500: Waveguide tube
410, 510: Waveguide part
411, 511: Opening
420, 520: Flange
430, 530: Waveguide tube main body

What is claimed is:

1. A method for manufacturing a mesh structure for an antenna reflection mirror, an electromagnetic shield, or a waveguide tube comprising:
providing a bundled wire that comprises a first element, and a second element, the first element being a zirconium copper wire, a stainless steel wire, or a combination of zirconium copper wire and stainless steel wire, and the second element being a dissolvable fiber;
making a first fabric with the bundled wire;
dissolving the second element to make a second fabric; and
making the mesh structure for the antenna reflection mirror, the electromagnetic shield, or the waveguide tube with the second fabric.

2. The method of claim 1, wherein the dissolvable fiber is water soluble, and the dissolving step includes immersing the first fabric in water.

3. The method of claim 2, wherein the second element is made of a material selected from the group consisting of a resol-type phenol resin, a methylolated urea (urea) resin, a methylolated melamine resin, polyvinyl alcohol, polyethylene oxide, polyacrylamide, and carboxymethyl cellulose.

4. The method of claim 1, wherein the fabric is knitted fabric.

5. The method of claim 4, wherein the knitted fabric is made with tricot stitch, knit stitch, stockinette stitch, double atlas stitch, or single satin stitch.

6. The method of claim 4, wherein the making the mesh structure for the antenna reflection mirror with the second fabric includes selecting a size of a knitting width of the first fabric according to the wavelength of the radio waves transmitted and received by the antenna reflection mirror.

7. The method of claim 1, wherein the fabric is woven fabric.

8. The method of claim 7, wherein the woven fabric is formed by weaving the first element and the second element with plain weave, satin weave, or twill weave.

9. The method of claim 1, wherein the zirconium copper wire and the stainless steel wire are plated wires.

10. The method of claim 1, wherein the first element and the second element are twisted to form the bundled wire.
